(19) United States
(12) Patent Application Publication
(10) Pub. No.: US 2026/0358369 A1
(43) Pub. Date: Nov. 12, 2026

(54) TEST PROBE

(71) Applicant: LEENO INDUSTRIAL INC., Busan (KR)

(72) Inventor: Sunghyun CHO, Busan (KR)

(73) Assignee: LEENO INDUSTRIAL INC., Busan (KR)

(21) Appl. No.: 19/137,186

(22) PCT Filed: Dec. 21, 2023
(86) PCT No.: PCT/KR2023/021234

§ 371 Date: Jun. 9, 2025

(30) Foreign Application Priority Data
Dec. 22, 2022 (KR) 10-2022-0181541

(51) Int. Cl. G01R 1/067

(52) U.S. Cl. CPC G01R 1/06722; G01R 1/06738

(57) ABSTRACT

Disclosed is a test probe for testing electrical characteristics of a subject-to-be-tested. The test probe includes: a cylindrical barrel comprising main securing protrusions that protrude inward and face each other; and a terminal including: a contact portion that comes into contact with the subject-to-be-tested, a securing portion that has a polygonal cross-section, extends integrally from the contact portion, and is inserted in a first end portion of the barrel, and an engaging portion that protrudes from a first surface of the polygonal cross-section toward the main securing protrusion, extends in a lengthwise direction of the securing portion, and includes a main securing groove recessed to insert the main securing protrusion therein.

### TECHNICAL FIELD

The disclosure relates to a test probe for testing the electrical characteristics of a subject-to-be-tested such as a semiconductor.

### BACKGROUND ART

A test probe includes a cylindrical barrel, a first plunger partially inserted in and secured to a first end of the barrel, a second plunger partially inserted in a second end of the barrel and movable sliding in the barrel, and a spring inserted in the barrel and providing elasticity to the second plunger. Each of the first plunger and the second plunger includes a cylindrical barrel insertion portion corresponding to the barrel shaped like a cylinder, and a contact portion to come into contact with a test contact point. To manufacture the first plunger and the second plunger, precise machining is required for a cylindrical base material. However, the precise machining of the first plunger and the second plunger increases the manufacturing cost of the test probe.

### DISCLOSURE OF INVENTION

### Technical Problem

An aspect of the disclosure is to provide a test probe, the manufacturing cost of which is reduced.

### Solution to Problem

According to an embodiment of the disclosure, there is provided a test probe. The test probe includes: a cylindrical barrel including main securing protrusions that protrude inward and face each other; and a terminal including: a contact portion that comes into contact with the subject-to-be-tested, a securing portion that has a polygonal cross-section, extends integrally from the contact portion, and is inserted in a first end portion of the barrel, and an engaging portion that protrudes from a first surface of the polygonal cross-section toward the main securing protrusion, extends in a lengthwise direction of the securing portion, and includes a main securing groove recessed to insert the main securing protrusion therein.

The securing portion may include a sub securing groove recessed on the first surface with the main securing groove therebetween in a direction transverse to the lengthwise direction.

The barrel may include sub securing protrusions that protrude inwards with the main securing protrusion therebetween.

The sub securing protrusion may be inserted in the sub securing groove as the securing portion is turned inside the barrel.

The terminal may be manufactured by a micro-electromechanical system (MEMS) process.

The terminal may include a plurality of cross-sectional layers different in cross-section from each other.

The contact portion may include a contact tip that comes into contact with the subject-to-be-tested, and the contact tip and the engaging portion may be provided in one of the plurality of cross-sectional layers.

The protruding length of the main securing protrusion may range from 5% to 7% of the diameter of the barrel.

The protruding length of the engaging portion may range from 7% to 10% of the diameter of the barrel.

The depth of the main securing groove may range from 4% to 5% of the diameter of the barrel.

### Advantageous Effects of Invention

A test probe according to an embodiment of the disclosure can reduce manufacturing costs by applying a terminal mass-produced by the MEMS process. In addition, the terminal can be stably fixedly coupled to a cylindrical barrel while having a polygonal cross-sectional shape according to the MEMS process manufacturing.

### BRIEF DESCRIPTION OF DRAWINGS

FIG. 1 is a perspective view of a test probe according to an embodiment of the disclosure.

FIG. 2 is an exploded perspective view of the test probe of FIG. 1.

FIG. 3 is a perspective view of a terminal of FIG. 1.

FIG. 4 is a view for describing a method of manufacturing the terminal of FIG. 3.

FIG. 5 is a perspective view showing a cross section cut along line A-A of FIG. 1.

FIG. 6 is a cross-sectional view taken along line B-B of FIG. 1.

FIG. 7 is a cross-sectional view showing that a terminal in FIG. 6 is turned 45 degrees counterclockwise.

### BEST MODE FOR CARRYING OUT THE INVENTION

Below, the test probe according to an embodiment of the disclosure will be described in detail with reference to the accompanying drawings.

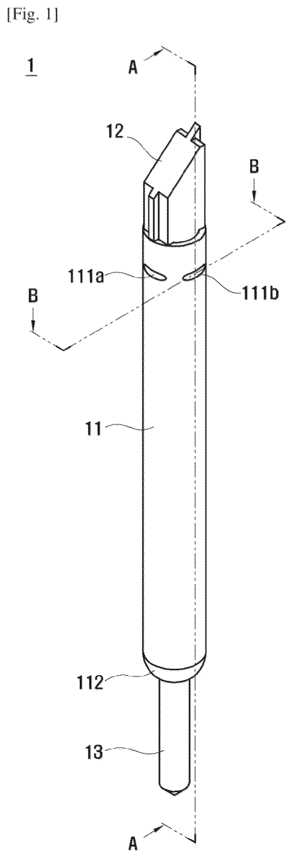

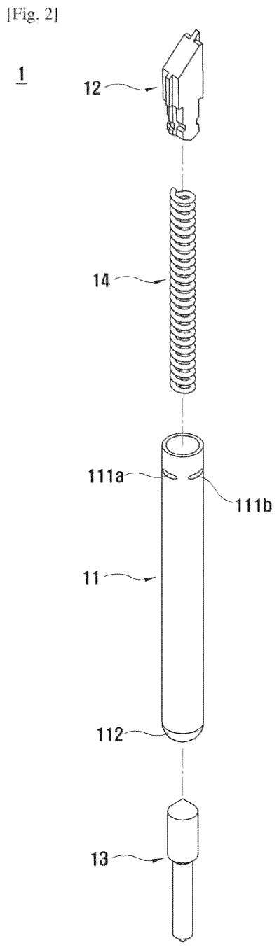

FIG. 1 is a perspective view of a test probe 1 according to an embodiment of the disclosure, and FIG. 2 is an exploded perspective view of the test probe 1 of FIG. 1.

The test probe 1 includes a barrel 11, a terminal 12 inserted in and secured to a first end portion of the barrel 11, a plunger 13 inserted in a second end portion of the barrel 11, and a spring 14 inserted in the barrel 11.

The barrel 11 is shaped like a hollow cylinder and made of a conductive material. The barrel 11 includes four securing protrusions 111a and 111b radially formed in and protruding inward from the first end portion thereof. The four securing protrusions 111a and 111b are arranged at intervals of about 90 degrees with respect to the circumferential surface of the barrel 11. The four securing protrusions 111a and 111b may be formed by caulking that punches the outer circumferential surface of the barrel 11 to be recessed inwardly. The four securing protrusions 111a and 111b include a pair of main securing protrusions 111a facing each other, and a pair of sub securing protrusions 111b adjacent to the main securing protrusions 111a and facing to each other.

The terminal 12 is made of a conductive material, and is fixedly coupled to the first end portion of the barrel 11 so as to come into contact with, for example, a test contact point of a subject-to-be-tested, such as a semiconductor. In this case, the fixed coupling may be achieved by coupling between the main securing protrusions 111a of the barrel 11 and a main securing groove 123c (to be described later) of the terminal 12. Detailed descriptions of the terminal 12 will be made later.

The plunger 13 is made of a conductive material, and is partially inserted in the second end portion of the barrel 11 so as to come into contact with, for example, a test contact point of a test circuit board. In this case, the plunger 13 may slide inside the barrel 11 while being partially inserted in the barrel 11. The plunger 13 is movable inside the barrel 11 but does not fall out of the barrel 11 because the second end portion of the barrel 11 is narrowed.

The spring 14 is placed inside the barrel 11 and compressed or restored as the plunger 13 slides, thereby providing the elasticity to the plunger 13.

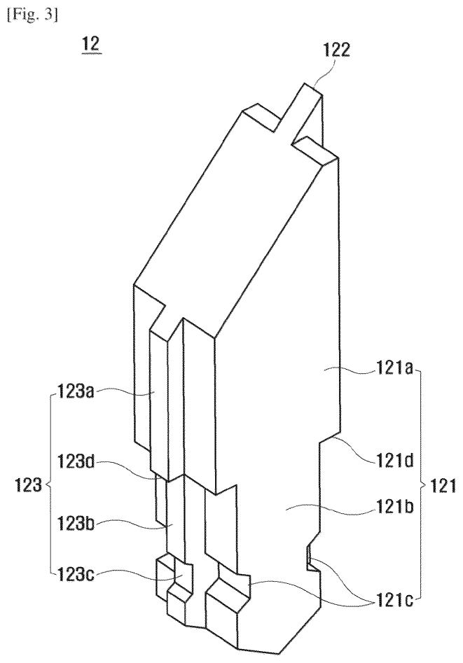

FIG. 3 is a perspective view of the terminal 12 of FIG. 1.

Referring to FIG. 3, the terminal 12 includes a body 121, a contact tip 122, and a pair of engaging portions 123.

The body 121 includes a contact portion 121a that comes into contact with a subject-to-be-tested, and a securing portion 121b that is inserted in the first end portion of the barrel 11. The body 121 has a polygonal, e.g., rectangular cross-section in a direction transverse to a lengthwise direction.

The contact portion 121a has an inclined end portion in an upper end thereof. The contact tip 122 is provided at the edge of the end portion of the contact portion 121a.

The diagonal length of the rectangular cross-section of the contact portion 121a is greater than the inner diameter of the barrel 11. As a result, the contact portion 121a is not inserted in the barrel 11.

The securing portion 121b extends integrally from the contact portion 121a. The securing portion 121b has a substantially square cross-section. The diagonal length of the square cross-section of the securing portion 121b is equal to or smaller than the inner diameter of the barrel 11 so that the securing portion 121b can be inserted in the barrel 11.

The securing portion 121b includes a pair of sub securing grooves 121c provided in first and second surfaces opposite to each other. The pair of sub securing grooves 121c are engaged with the pair of sub securing protrusions 111b when the terminal 12 is turned inside the barrel 11.

Between the contact portion 121a and the securing portion 121b is formed a stepped portion 121d. The stepped portion 121d is caught on the first end portion of the barrel 11 and prevented from entering the barrel 11 when the securing portion 121b is inserted in the barrel 11.

The pair of engaging portions 123 includes a pair of first engaging portions 123a respectively protruding from a first surface of the contact portion 121a and a second surface opposite to the first surface, and a pair of second engaging portions 123b respectively protruding from a first surface of the securing portion 121b and a second surface opposite to the first surface toward the main securing protrusions 111a of the barrel 11. Each pair of first and second engaging portions 123a and 123b are extended along the lengthwise direction on the first surface of the body 121 and the second surface opposite to the first surface.

The pair of first engaging portions 123a are provided with the pair of main securing groove 123c at positions corresponding to the pair of main securing protrusions 111a. When the outer circumferential surface of the barrel 11 where the pair of main securing grooves 123c are placed is transformed by the caulking to form the pair of main securing protrusions 111a in the state that the securing portion 121b is inserted in the first end portion of the barrel 11, the securing portion 121b is fixedly coupled to the first end portion of the barrel 11.

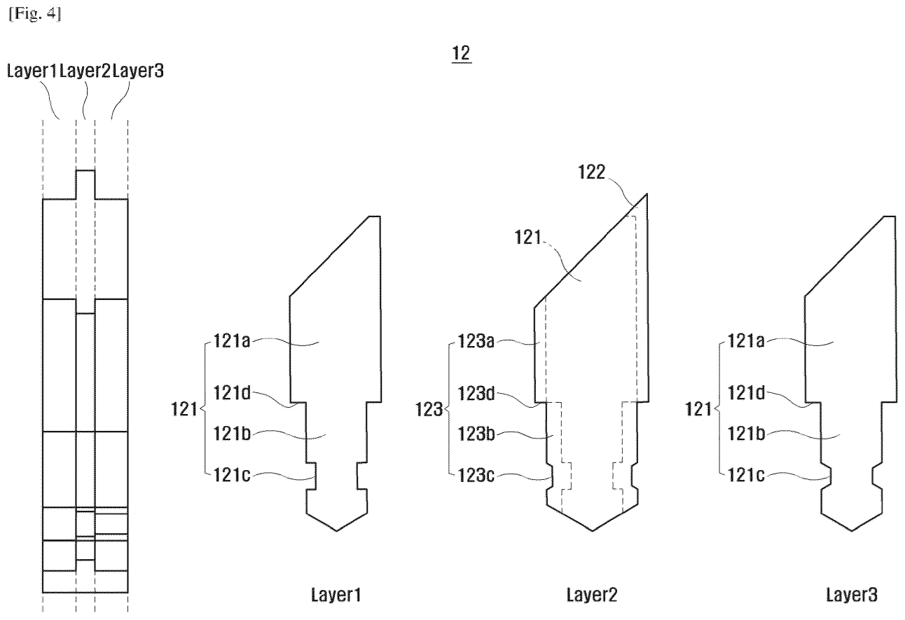

FIG. 4 is a view for describing a method of manufacturing the terminal 12 of FIG. 3.

Referring to FIG. 4, the terminal 12 may be divided into three sections Layer1 to Layer3 and manufactured by deposition and etching. In this way, the terminal 12 has a simple structure that can be manufactured by the minimum number of micro-electromechanical system (MEMS) processes.

The section Layer1 refers to a pattern corresponding to a part of the body 121 manufactured by a first MEMS step.

The section Layer2 refers to a pattern corresponding to a part, i.e., the contact tip 122 and the engaging portion 123 of the body 121 manufactured by a first MEMS step.

The section Layer3 refers to a pattern corresponding to the remaining part of the body 121 manufactured by the first MEMS step.

As described above, the terminal 12 for the test probe 1 may be mass-produced by the MEMS process.

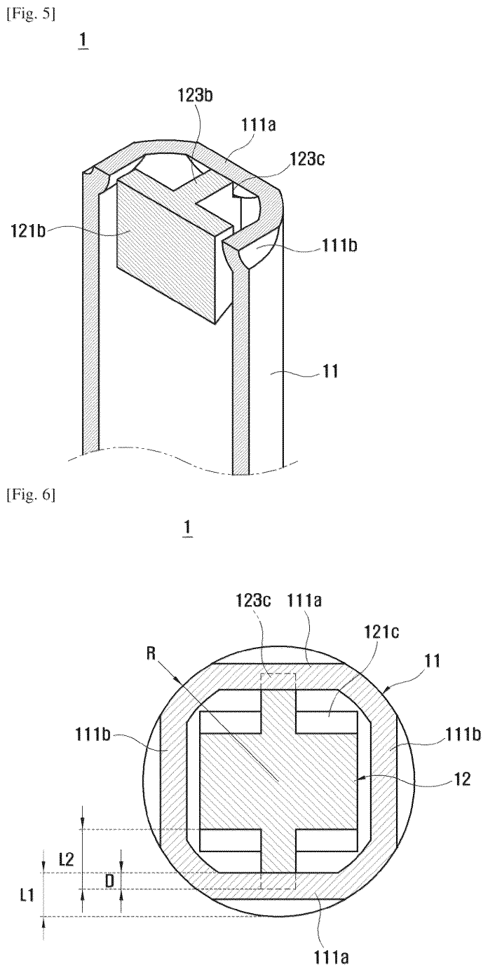

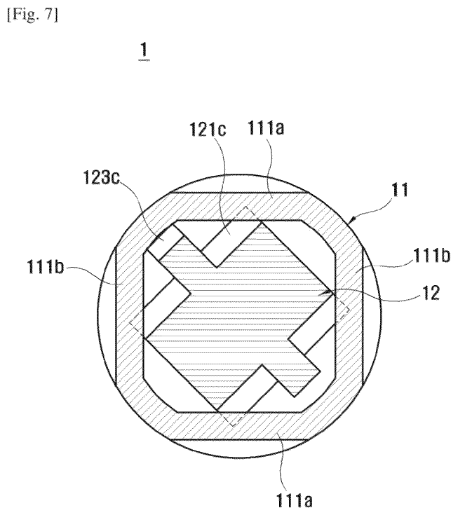

FIG. 5 is a perspective view showing a cross section cut along line A-A of FIG. 1. FIG. 6 is a cross-sectional view taken along line B-B of FIG. 1. FIG. 7 is a cross-sectional view showing that a terminal in FIG. 6 is turned 45 degrees counterclockwise.

Referring to FIGS. 5 and 6, the securing portion 121b is secured to the barrel 110 by the engagement between the pairs of main securing protrusions 111a and main securing grooves 123c. The engagement between the main securing protrusion 111a and the main securing groove 123c is difficult to remain stable because the main securing protrusion 111a has an elliptical curved shape at the inner side. When the terminal 12 is turned inside the barrel 11 counterclockwise, for example, 45 degrees as shown in FIG. 7 during the test of the test probe 1, the pairs of main securing protrusions 111a and main securing groove 123c are released from the engagement, but the pair of sub securing protrusions 111b are coupled to the pair of sub securing grooves 121b, respectively. As a result, the terminal 12 is stably secured and supported in the barrel 11 even though the terminal 12 is turned inside the barrel 11.

Because the securing portion 121c of the terminal 12 is shaped like a quadrangular pillar but the barrel 11 has a circular hollow, there is unavoidably a gap between the inner curved surface of the barrel 11 and the surface of the securing portion 121c. To secure the securing portion 121c to the barrel 11, the securing groove is formed on the surface of the securing portion 121c and the securing protrusion to be inserted in the securing groove is formed by caulking the outer circumferential surface of the barrel 11. However, if the gap is too large, the amount of transformation (the protruding length L1 of the securing protrusion) in the barrel 11 due to the caulking is also increased, thereby causing the barrel 11 to become defective due to excessive deformation. To solve this problem, the terminal 12 according to an embodiment of the disclosure includes the second engaging portion 123b protruding from the first surface of the securing portion 121c, and the main securing groove 123c, so that the amount of transformation (the protruding length L1 of the securing protrusion) in the barrel 11 due to the caulking can be decreased.

If the amount of transformation (the protruding length L1 of the securing protrusion) in the barrel 11 due to the caulking is too small, the degree of engagement between the main securing protrusion 111a and the main securing groove 123c also becomes too small, thereby causing difficulty in stable fixed coupling.

For the fixed coupling between the securing portion 121c and the barrel 11, the protruding length L1 of the main securing protrusion 111a, the protruding length L2 of the second engaging portion 123b, and the depth D of the main securing groove 123c were optimally set based on the diameter R of the barrel 11 as follows.

The protruding length L1 of the main securing protrusion 111a may range from 5% to 7% of the diameter R of the barrel 11. When the protruding length L1 is smaller than 5% of the diameter R of the barrel 11, the protruding length L2 of the second engaging portion 123b becomes longer and the width thereof becomes narrower, thereby lowering the durability of the second engaging portion 123b. On the other hand, when the protruding length L1 is greater than 7% of the diameter R of the barrel 11, the durability of the second engaging portion 123b is improved but the barrel 11 may be damaged due to the excessive deformation of the barrel 11.

The protruding length L2 of the second engaging portion 123b may range from 7% to 10% of the diameter R of the barrel 11. When the protruding length L2 is smaller than 7% of the diameter R of the barrel 11, the amount of transformation in the barrel 11 becomes relatively larger, thereby causing the barrel 11 to be damaged. On the other hand, when the protruding length L2 is greater than 10% of the diameter R of the barrel 11, the protruding length L2 of the second engaging portion 123b becomes longer and the width thereof become narrower, thereby lowering the durability of the second engaging portion 123b.

The depth D of the main securing groove 123c may range from 4% to 5% of the diameter R of the barrel 11. When the depth D of the main securing groove 123c is smaller than 4% of the diameter R of the barrel 11, the stable fixed coupling is not stably maintained because the degree of engagement between the main securing protrusion 111a having the elliptical curved shape and the main securing groove 123c is reduced. When the depth D of the main securing groove 123c is greater than 5% of the diameter R of the barrel 11, the width of the main securing protrusions 111a becomes wider and the amount of transformation in the barrel 11 becomes larger, thereby causing the barrel 11 to be damaged.

According to an embodiment of the disclosure, the manufacturing costs of the test probe are reduced by replacing the plunger secured to the barrel with the terminal mass-produced by the MEMS process. Further, the terminal having the polygonal cross-section based on the manufacture of the MEMS process may be stably and fixedly coupled to the cylindrical barrel.

Although exemplary embodiments of the disclosure have been shown and described, the disclosure is not limited to the foregoing specific embodiments, various alternative modifications can be embodied by a person having an ordinary skill in the art without departing from the scope of the disclosure as claimed in the appended claims, and such modified embodiments should not be understood separately from the technical sprit or prospect of the disclosure.

1. A test probe for testing electrical characteristics of a subject-to-be-tested, the test probe comprising:
a cylindrical barrel comprising main securing protrusions that protrude inward and face each other; and
a terminal comprising:
a contact portion that comes into contact with the subject-to-be-tested,
a securing portion that has a polygonal cross-section, extends integrally from the contact portion, and is inserted in a first end portion of the barrel, and
an engaging portion that protrudes from a first surface of the polygonal cross-section toward the main securing protrusion, extends in a lengthwise direction of the securing portion, and comprises a main securing groove recessed to insert the main securing protrusion therein.

2. The test probe of claim 1, wherein the securing portion comprises a sub securing groove recessed on the first surface with the main securing groove therebetween in a direction transverse to the lengthwise direction.

3. The test probe of claim 2, wherein the barrel comprises sub securing protrusions that protrude inwards with the main securing protrusion therebetween.

4. The test probe of claim 3, wherein the sub securing protrusion is inserted in the sub securing groove as the securing portion is turned inside the barrel.

5. The test probe of claim 1, wherein the terminal is manufactured by a micro-electromechanical system (MEMS) process.

6. The test probe of claim 5, wherein the terminal comprises a plurality of cross-sectional layers different in cross-section from each other.

7. The test probe of claim 6, wherein
the contact portion comprises a contact tip that comes into contact with
the subject-to-be-tested, and
the contact tip and the engaging portion are provided in one of the plurality of cross-sectional layers.

8. The test probe of claim 1, wherein a protruding length of the main securing protrusion ranges from 5% to 7% of a diameter of the barrel.

9. The test probe of claim 1, wherein a protruding length of the engaging portion ranges from 7% to 10% of a diameter of the barrel.

10. The test probe of claim 1, wherein a depth of the main securing groove ranges from 4% to 5% of a diameter of the barrel.
